(19) United States
(12) Patent Application Publication
(10) Pub. No.: US 2025/0143020 A1
(43) Pub. Date: May 1, 2025

(54) LIGHT-EMITTING DIODE AND LIGHT-EMITTING DEVICE INCLUDING THE SAME

(71) Applicant: TIANJIN SANAN OPTOELECTRONICS CO., LTD., Tianjin (CN)

(72) Inventors: Weihuan LI, Tianjin (CN); Fuyang NING, Tianjin (CN); Liwei WANG, Tianjin (CN); Kunhuang CAI, Tianjin (CN); Han-Xin LIU, Tianjin (CN); Xiaofeng LIU, Xiamen (CN); Lingfei WANG, Xiamen City (CN); Yuehua JIA, Tianjin (CN)

(21) Appl. No.: 18/929,905

(22) Filed: Oct. 29, 2024

(30) Foreign Application Priority Data
Oct. 31, 2023 (CN) 202311437001.8

(51) Int. Cl. H01L 33/14; H01L 25/075; H01L 33/02; H01L 33/06; H01L 33/30; H01L 33/62

(52) U.S. Cl. CPC H10H 20/816; H01L 25/0753; H10H 20/812; H10H 20/8215; H10H 20/824; H10H 20/857

(57) ABSTRACT

A light-emitting diode includes a semiconductor epitaxial structure which includes a first semiconductor layer, an active layer, and a second semiconductor layer that are stacked in sequence. The second semiconductor layer includes a current spreading layer, which includes a first doped layer doped with a first p-type impurity, a second doped layer doped with the first p-type impurity and a second p-type impurity, and a third doped layer doped with the second p-type impurity. A concentration of the first p-type impurity in the first doped layer is less than or equal to a concentration of the first p-type impurity in the second doped layer. A concentration of the second p-type impurity in the third doped layer is greater than a concentration of the second p-type impurity in the second doped layer. A light-emitting device including the aforesaid light-emitting diode is also provided.

### CROSS-REFERENCE TO RELATED APPLICATION

This application claims priority to Chinese Invention Patent Application No. CN202311437001.8, filed on Oct. 31, 2023, the entire disclosure of which is incorporated by reference herein.

### FIELD

The disclosure relates to a light-emitting diode and a light-emitting device including the same.

### BACKGROUND

At present, light-emitting diodes (LEDs) have been widely applied in two fields, i.e., the illumination field and the display field, due to their advantages of high efficiency, long service life, being in all solid-state, self-illumination property, and satisfying green environmental protection concept. Specifically, the LEDs are broadly employed in, for instances, lighting, high-definition studios, high-end cinemas, office displays, and other fields. However, conventional LEDs still have a poor current spreading problem, resulting in poor luminous efficiency thereof.

### SUMMARY

Accordingly, in a first aspect, the present disclosure provides a light-emitting diode, which can alleviate at least one of the drawbacks of the prior art.

The light-emitting diode includes a semiconductor epitaxial structure that includes a first semiconductor layer, an active layer, and a second semiconductor layer that are stacked in sequence. The second semiconductor layer includes a current spreading layer. The current spreading layer includes a first doped layer doped with a first p-type impurity, a second doped layer doped with the first p-type impurity and a second p-type impurity, and a third doped layer doped with the second p-type impurity. The first doped layer, the second doped layer and the third doped layer are stacked in sequence in a direction from the first semiconductor layer to the second semiconductor layer.

A concentration of the first p-type impurity in the first doped layer is less than or equal to a concentration of the first p-type impurity in the second doped layer. In addition, a concentration of the second p-type impurity in the third doped layer is greater than a concentration of the second p-type impurity in the second doped layer.

In a second aspect, the present disclosure provides a light-emitting device, which can alleviate at least one of the drawbacks of the prior art. The light-emitting device includes the aforesaid light-emitting diode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a semiconductor epitaxial structure of a light-emitting diode according to an embodiment of the present disclosure.

FIG. 2 is a schematic view illustrating a second semiconductor layer of the semiconductor epitaxial structure of the light-emitting diode according to the present disclosure.

FIG. 3 is a schematic view illustrating a first semiconductor layer of the semiconductor epitaxial structure of the light-emitting diode according to the present disclosure.

FIG. 4 is a schematic view illustrating an active layer of the semiconductor epitaxial structure of the light-emitting diode according to the present disclosure.

FIG. 5 is a secondary-ion mass spectrometry (SIMS) profile showing depth versus concentration of elements for a current spreading layer of the second semiconductor layer of the semiconductor epitaxial structure of the light-emitting diode according to the present disclosure.

FIG. 6 is a schematic view illustrating a light-emitting diode according to another embodiment of the present disclosure, which includes the semiconductor epitaxial structure shown in FIG. 1.

FIG. 7 is a schematic view illustrating a light-emitting device according to still another embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly. In addition, when a layer is referred to as “between” two layers, it can be the only layer between the two layers, or one or more intervening layers may also be present. As used herein, “between” means including both endpoint values.

The following describes the implementation of the present disclosure through specific embodiments. Those skilled in the art can easily understand other advantages and effects of the present disclosure from the content in this specification. Implementation or application of the present disclosure can also be achieved through other different specific embodiments. Various details in this specification may also be modified or changed in various ways based on different viewpoints and applications without departing from the spirit of the present disclosure.

When describing the embodiments of the present disclosure in detail, for convenience of explanation, a cross-sectional view showing a structure of a device will not be partially enlarged according to the general scale, and the cross-sectional view is a schematic drawing merely for illustration purpose, which shall not use to limit the scope for protection of the present disclosure. In addition, three-dimensional space dimensions of length, width and depth should be included in practice.

In the context of the present disclosure, a structure described as having a first feature “on” a second feature may include embodiments in which the first feature and the second feature are formed in direct contact, or alternatively, may include embodiments in which an additional feature is formed between the first feature and the second feature thus that the first feature and the second feature may not be in direct contact.

It should be noted that the drawings provided for the embodiments are only for schematically illustrating the basic concept of the present disclosure. Therefore, the drawings only show components related to the present disclosure and are not drawn according to the number, shape and size of the components during actual implementation. In actual implementation, the shape, quantity and proportion of each component can be changed at will, and the component layout may also be more complex.

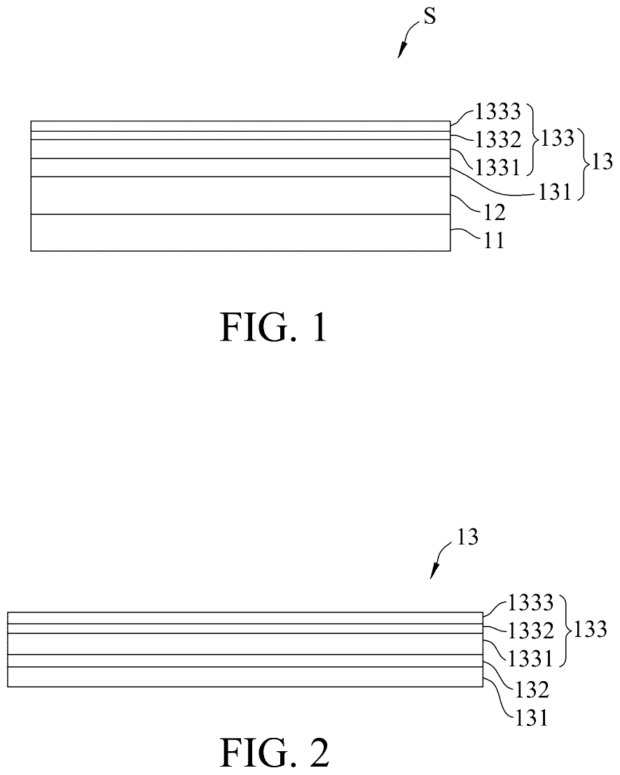

FIG. 1 is a schematic view illustrating a semiconductor epitaxial structure (S) of a light-emitting diode according to an embodiment of the present disclosure. Referring to FIG. 1, the semiconductor epitaxial structure (S) includes a first semiconductor layer 11, an active layer 12, and a second semiconductor layer 13 that are stacked in sequence. A side of the active layer 12 facing the second semiconductor layer 13 is designated as an upper surface thereof, and another side of the active layer 12 opposite to the upper surface and facing the first semiconductor layer 11 is designated as a bottom surface thereof.

In certain embodiments, the second semiconductor layer 13 includes a current spreading layer 133, which includes a first doped layer 1331 doped with a first p-type impurity, a second doped layer 1332 doped with the first p-type impurity and a second p-type impurity, and a third doped layer 1333 doped with the second p-type impurity. The first doped layer 1331, the second doped layer 1332 and the third doped layer 1333 are stacked in sequence in a direction from the first semiconductor layer 11 to the second semiconductor layer 13. Moreover, a concentration of the first p-type impurity in the first doped layer 1331 is less than or equal to a concentration of the first p-type impurity in the second doped layer 1332, and a concentration of the second p-type impurity in the third doped layer 1333 is greater than a concentration of the second p-type impurity in the second doped layer 1332.

In some embodiments, a thickness of the current spreading layer 133 is T, a thickness of the first doped layer 1331 is T1, a thickness of the second doped layer 1332 is T2, and a thickness of the third doped layer 1333 is T3, where T1>0.5T, and T3 ranges from 200 Å to 1000 Å. In an exemplary embodiment, the thickness of the current spreading layer 133 is equal to a sum of the thickness of the first doped layer 1331 (i.e., T1), the thickness of the second doped layer 1332 (i.e., T2), and the thickness of the third doped layer 1333 (i.e., T3). In other words, T=T1+T2+T3. The current spreading layer 133 may be made of gallium phosphide (GaP).

In some embodiments, the concentration of the first p-type impurity in the first doped layer 1331 is 5E17-4E18 atoms/cm³, and the concentration of the second p-type impurity in the third doped layer 1333 is 4E18-4E20 atoms/cm³. The first p-type impurity may be magnesium (Mg), zinc (Zn), calcium (Ca), or barium (Ba), and the second p-type impurity may be carbon (C), Zn, Ca, or Ba. It should be noted that the first p-type impurity and the second p-type impurity are different. In an exemplary embodiment, the first p-type impurity is Mg, and the second p-type impurity is C.

In other embodiments, the second semiconductor layer 13 of the present disclosure further includes a p-type cladding layer 131 disposed between the current spreading layer 133 and the active layer 12. The p-type cladding layer 131 is made of aluminum gallium indium phosphide (AlGaInP) or aluminum indium phosphide (AlInP). In an exemplary embodiment, a distance from the first doped layer 1331 to the p-type cladding layer 131 is less than a distance from the third doped layer 1333 to the p-type cladding layer 131, and the second doped layer 1332 is disposed between the first doped layer 1331 and the third doped layer 1333. In an exemplary embodiment, Mg and C are used together as p-type doping elements (i.e., the first and second p-type impurities) of the current spreading layer 133. By co-doping of Mg and C, since C is more active than Mg, a concentration of the p-type doping elements of the current spreading layer 133 is elevated, which can further reduce the voltage of the light-emitting diode, and increase the brightness as well as enhance the antistatic property thereof. Furthermore, by limiting the distance from the first doped layer 1331 doped with the first p-type impurity (e.g., Mg) to the p-type cladding layer 131 to be less than the distance from the third doped layer 1333 doped with the second p-type impurity (e.g., C) to the p-type cladding layer 131, spreading of more active C, which has good spreading ability, into the p-type cladding layer 131 and the active layer 12 can be prevented, thereby reducing adverse effect to the brightness and reliability of the light-emitting diode 22.

The above is an exemplary description regarding the embodiment of the semiconductor epitaxial structure (S) according to the present disclosure with reference to FIG. 1. Implementation of the semiconductor epitaxial structure (S) in the light-emitting diode provides advantages of a reduced internal resistance, an improved current spreading capability, an increased luminous brightness, a reduced LED lighting voltage and an enhanced antistatic performance to the light-emitting diode.

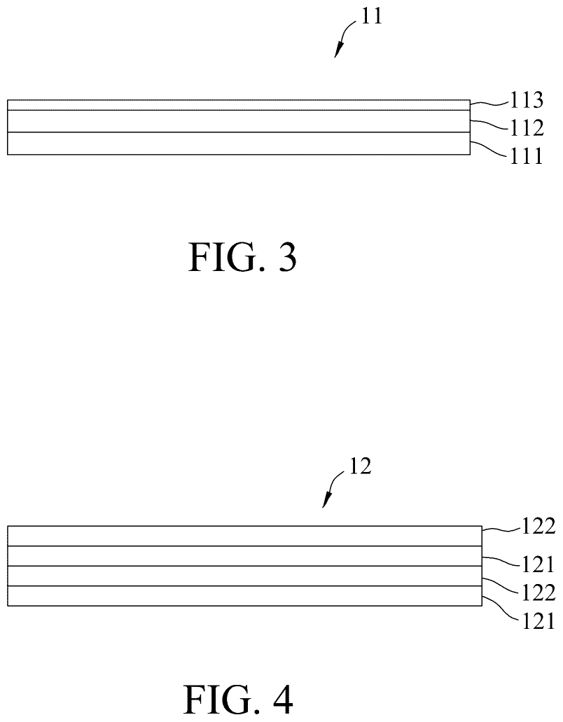

FIG. 2 is a schematic view illustrating the second semiconductor layer 13 of the semiconductor epitaxial structure (S) of the light-emitting diode according to the present disclosure. FIG. 3 is a schematic view illustrating the first semiconductor layer 11 of the semiconductor epitaxial structure (S) of the light-emitting diode according to the present disclosure. FIG. 4 is a schematic view illustrating the active layer 12 of the semiconductor epitaxial structure (S) of the light-emitting diode according to the present disclosure. In the following description, details of the semiconductor epitaxial structure (S) shown in FIG. 1 are manifested by the second semiconductor layer 13 shown in FIG. 2, the first semiconductor layer 11 shown in FIG. 3, and the active layer 12 shown in FIG. 4.

Referring to FIG. 2, in some embodiments, the second semiconductor layer 13 of the present disclosure may further include the lattice transition layer 132 disposed between the p-type cladding layer 131 and the current spreading layer 133. The lattice transition layer 132 may be made of AlGaInP, so as to function as a transition layer and to reduce defects caused by lattice mismatch between the p-type cladding layer 131 and the current spreading layer 133

Referring to FIG. 3, in some embodiments, the first semiconductor layer 11 may further include an n-type contact layer 111, an n-type window layer 112, and an n-type cladding layer 113. The n-type cladding layer 113, the n-type window layer 112 and the n-type contact layer 111 are sequentially arranged in such order in a direction away from the bottom surface of the active layer 12. That is to say, the n-type cladding layer 113 is disposed on a side of the n-type window layer 112 proximal to the active layer 12, and the n-type contact layer 111 is disposed on a side of the n-type window layer 112 facing away from the active layer 12. The n-type contact layer 111 is used to form a good ohmic contact (which can reduce contact resistance) with electrodes which will be formed in subsequent processing steps of the light-emitting diode. The n-type window layer 112 is disposed on a side of the n-type cladding layer 113 facing away from the active layer 12, and serves as a light-emitting surface of the light-emitting diode. In certain embodiments, the n-type window layer 112 may be made of AlGaInP or AlInP, and an n-type doping element therein may be silicon (Si), germanium (Ge), or tin (Si). The n-type cladding layer 113 is closely adjacent to the active layer 12, and can provide electrons or holes for the active layer 12. The n-type cladding layer 113 may be made of AlGaInP or AlInP, and an n-type doping element therein may be Si. Because Si has a relatively fast migration rate, provision thereof ensures a sufficient supply of electrons, thereby assuring the light-emitting diode 22 has a desired light extraction rate and simultaneously, a reduction of the voltage thereof.

The active layer 12 provides a light radiation area where recombination of electrons and holes occurs, and material selection of the active layer 12 can be made according to a desired wavelength of emitted light. Referring to FIG. 4, the active layer 12 may be a periodic layered structure including barrier layers 121 and well layers 122 alternately stacked with the barrier layers 121. In some embodiments, the active layer 12 includes N number of periods of quantum well structures, and each period of the quantum well structures includes one of the barrier layers 121 and one of the well layers 122 deposited sequentially, in which the barrier layer 121 has a band gap larger than that of the well layer 122. By adjusting the composition ratio of semiconductor materials in the active layer 12, the active layer 12 is capable of radiating light with a desired wavelength. The active layer 12 is a material layer that provides electroluminescent radiation. In an example, the barrier layers 121 may be made of gallium nitride (GaN), aluminum gallium nitride (AlGaN), AlGaInP, or aluminum gallium arsenide (AlGaAs), and the well layers 122 may be made of indium gallium nitride (InGaN), AlGaInP, or indium gallium arsenide (InGaAs). A period number of the active layer 12 (i.e., the periodic layered structure) ranges from 2 to 100. Additionally, each of the well layers 122 of the periodic layered structure has a thickness ranging from 2 nm to 25 nm, and each of the barrier layers 121 of the periodic layered structure has a thickness ranging from 2 nm to 25 nm. It should be noted that in the present disclosure, the thickness of each of the well layers 122 may be the same with or different from the thickness of each of the barrier layers 121, and the aforesaid thicknesses may be adjusted according to actual needs. Moreover, the active layer 12 emits light having a radiation wavelength ranging from 550 nm to 950 nm.

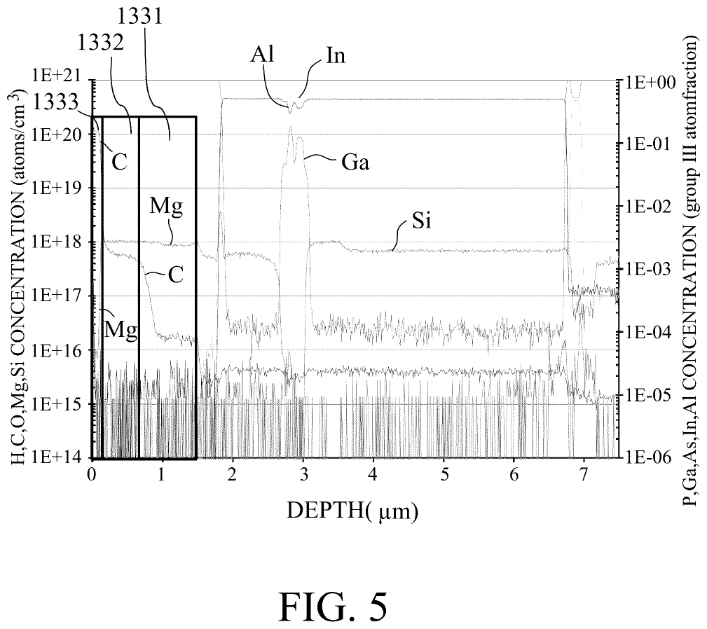

FIG. 5 is a secondary-ion mass spectrometry (SIMS) profile showing the distribution of each element in the light-emitting diode of this embodiment according to the present disclosure. As shown in FIG. 5, the concentration of the first p-type impurity in the first doped layer 1331 (i.e., an Mg doping concentration therein) is similar to the concentration of the first p-type impurity in the second doped layer 1332 (i.e., an Mg doping concentration therein), and both of the concentrations are at relatively high levels; nevertheless, the third doped layer 1333 has an Mg doping concentration that is greatly reduced compared thereto. In addition, the concentration of the second p-type impurity in the third doped layer 1333 (i.e., a C doping concentration therein) is relatively high, and the concentration of the second p-type impurity in the second doped layer 1332 (i.e., a C doping concentration therein) is lower than that in the third doped layer 1333. The first doped layer 1331 has a lowest C doping concentration among the three doped layers 1331, 1332, 1333. The distribution of concentration of each of the first p-type impurity (i.e., Mg) and the second p-type impurity (i.e., C) shown in FIG. 5 is consistent with the foregoing description regarding the doping concentrations in the current spreading layer 133 described hereinabove.

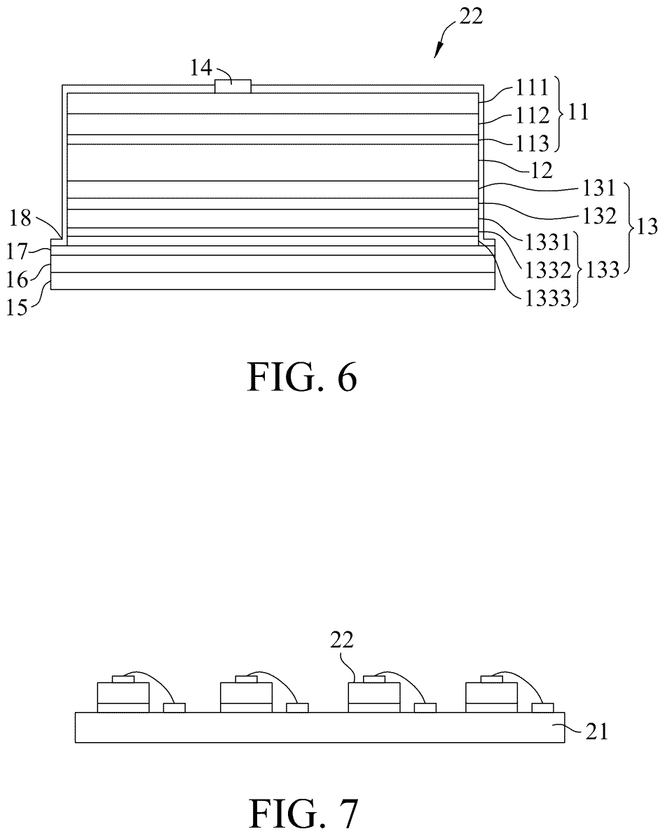

Referring to FIG. 6, a light-emitting diode 22 according to another embodiment of the present disclosure is configured as a vertical light-emitting diode. The light-emitting diode 22 incorporates the semiconductor epitaxial structure (S) shown in FIG. 1. Besides the semiconductor epitaxial structure (S), the light-emitting diode 22 includes two electrodes (i.e., a first electrode 14 and a second electrode 15) which are respectively located on both sides of the semiconductor epitaxial structure (S). Due to the vertical configuration of the vertical light-emitting diode 22, almost all current is allowed to flow vertically through the semiconductor epitaxial structure (S), so that the current distribution problem occurring in a horizontal light-emitting diode is alleviated and the luminous efficiency is improved.

Specifically, as shown in FIG. 6, the semiconductor epitaxial structure (S) has a first surface and a second surface opposite to the first surface. The first surface is closer to the first semiconductor layer 11 than the second surface. The semiconductor epitaxial structure (S) includes the second semiconductor layer 13, the active layer 12, and the first semiconductor layer 11, and the second semiconductor layer 13, the active layer 12 and the first semiconductor layer 11 are arranged one above the other along a direction from the second surface to the first surface. Moreover, the first semiconductor layer 11 may include the n-type contact layer 111, the n-type window layer 112, and the n-type cladding layer 113, and the n-type contact layer 111, the n-type window layer 112 and the n-type cladding layer 113 are arranged one above the other along a direction from the first surface to the second surface. In addition, the second semiconductor layer 13 may include the p-type cladding layer 131, the lattice transition layer 132, and the current spreading layer 133 that are arranged in sequence. Furthermore, the first semiconductor layer 11 is provided with the first electrode 14, and the current spreading layer 133 is provided with a substrate 16. The substrate 16 is a conductive substrate. The conductive substrate 16 is bonded to the second surface of the semiconductor epitaxial structure (S) of the light-emitting diode 22 by a substrate transferring process to accomplish bonding between the substrate 16 and the semiconductor epitaxial structure (S). The substrate 16 is bonded to the second surface of the semiconductor epitaxial structure (S) through a bonding layer 17, which is a conductive bonding layer. The second electrode 15 is provided on a bottom side of the substrate 16. That is to say, the first and second electrodes 14, 15 are located on different sides of the semiconductor epitaxial structure (S). In certain embodiments, the substrate 16 may be made of a material having a conductive property such as Si or silicon carbide (SiC), and the bonding layer 17 may be made of a metallic conductive material.

As shown in FIG. 6, the light-emitting diode 22 further includes an insulating protective layer 18, which is disposed on outer surfaces and sidewalls of the semiconductor epitaxial structure (S). In certain embodiments, the insulating protective layer 18 may be made of a non-conductive material selected from the group consisting of an inorganic tungsten oxide, a nitride, silicon dioxide, silicon nitride, titanium oxide, and combinations thereof.

Referring to FIG. 7, in still another embodiment of the present disclosure, a light-emitting device is provided, which includes a plurality of the light-emitting diodes 22 of the aforesaid embodiment of the present disclosure. The light-emitting diodes 22 may be micro light-emitting diodes (LED), mini LEDs, or standard LEDs. The light-emitting device can be applied to a backlight display or a red-green-blue (RGB) display screen. In the light-emitting device, several hundreds or thousands of the miniature light-emitting diodes 22 may be collectively and flip-chip mounted on an application substrate or a packaging substrate 21, so as to form a light source for the backlight display or the RGB display screen.

In sum, by virtue of doping two different p-type impurities, i.e., the first p-type impurity and the second p-type impurity, in the current spreading layer 133, and by virtue of allowing each of the two different p-type impurities to have different concentrations in the first doped layer 1331 and the second doped layer 1332, or in the second doped layer 1332 and the third doped layer 1333, the light-emitting diode 22 has improved current spreading capacity, reduced internal resistance, and enhanced brightness.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting diode, comprising:
a semiconductor epitaxial structure including a first semiconductor layer, an active layer, and a second semiconductor layer that are stacked in sequence;
wherein said second semiconductor layer includes a current spreading layer, said current spreading layer including a first doped layer doped with a first p-type impurity, a second doped layer doped with said first p-type impurity and a second p-type impurity, and a third doped layer doped with said second p-type impurity, said first doped layer, said second doped layer and said third doped layer being stacked in a direction from said first semiconductor layer to said second semiconductor layer,
wherein a concentration of said first p-type impurity in said first doped layer is less than or equal to a concentration of said first p-type impurity in said second doped layer, and
wherein a concentration of said second p-type impurity in said third doped layer is greater than a concentration of said second p-type impurity in said second doped layer.

2. The light-emitting diode as claimed in claim 1, wherein said concentration of said first p-type impurity in said first doped layer is 5E17-4E18 atoms/cm³.

3. The light-emitting diode as claimed in claim 1, wherein said first p-type impurity is magnesium.

4. The light-emitting diode as claimed in claim 1, wherein said concentration of said second p-type impurity in said third doped layer is 4E18-4E20 atoms/cm³.

5. The light-emitting diode as claimed in claim 1, wherein said second p-type impurity is carbon.

6. The light-emitting diode as claimed in claim 1, wherein a thickness of said current spreading layer is T, a thickness of said first doped layer is T1, a thickness of said second doped layer is T2, and a thickness of said third doped layer is T3, where T1>0.5T.

7. The light-emitting diode as claimed in claim 6, wherein T3 ranges from 200 Å to 1000 Å.

8. The light-emitting diode as claimed in claim 6, wherein T=T1+T2+T3.

9. The light-emitting diode as claimed in claim 1, wherein said current spreading layer is made of gallium phosphide (GaP).

10. The light-emitting diode as claimed in claim 1, wherein said second semiconductor layer further includes a p-type cladding layer disposed between said current spreading layer and said active layer, said p-type cladding layer being made of aluminum gallium indium phosphide (AlGaInP) or aluminum indium phosphide (AlInP).

11. The light-emitting diode as claimed in claim 10, wherein a distance from said first doped layer to said p-type cladding layer is less than a distance from said third doped layer to said p-type cladding layer.

12. The light-emitting diode as claimed in claim 10, wherein said second semiconductor layer further includes a lattice transition layer disposed between said p-type cladding layer and said current spreading layer.

13. The light-emitting diode as claimed in claim 1, wherein said first semiconductor layer includes an n-type window layer.

14. The light-emitting diode as claimed in claim 13, wherein said first semiconductor layer further includes an n-type cladding layer disposed on a side of said n-type window layer proximal to said active layer.

15. The light-emitting diode as claimed in claim 14, wherein said n-type cladding layer is made of AlGaInP or AlInP, and said n-type window layer is made of AlGaInP or AlInP.

16. The light-emitting diode as claimed in claim 14, wherein said first semiconductor layer further includes an n-type contact layer disposed on a side of said n-type window layer facing away from said active layer.

17. The light-emitting diode as claimed in claim 1, wherein said active layer is a periodic layered structure including well layers and barrier layers alternately stacked with said well layers, a period number of said periodic layered structure ranging from 2 to 100.

18. The light-emitting diode as claimed in claim 17, wherein a thickness of each of said well layers of said periodic layered structure ranges from 2 nm to 25 nm, and a thickness of each of said barrier layers of said periodic layered structure ranges from 2 nm to 25 nm.

19. The light-emitting diode as claimed in claim 1, wherein said active layer emits light having a radiation wavelength ranging from 550 nm to 950 nm.

20. A light-emitting device, comprising a light-emitting diode as claimed in claim 1.
